(19) United States
(12) Patent Application Publication
(10) Pub. No.: US 2025/0380364 A1
(43) Pub. Date: Dec. 11, 2025

(54) OVERLAPPING FLEXIBLE CIRCUIT BOARDS

(71) Applicant: Apple Inc., Cupertino, CA (US)

(72) Inventors: Jamie N. Forslin, San Jose, CA (US); Zhijia Xue, San Jose, CA (US); Ajinkya P. Ranade, Sunnyvale, CA (US); Poh Seong Chiu, Cupertino, CA (US); Danielle Loi, Cupertino, CA (US); Dominic Pitera, San Francisco, CA (US)

(21) Appl. No.: 19/225,628

(22) Filed: Jun. 2, 2025

Related U.S. Application Data
(60) Provisional application No. 63/656,946, filed on Jun. 6, 2024.

(51) Int. Cl. H05K 1/14; H05K 3/36

(52) U.S. Cl. CPC H05K 1/147; H05K 3/363

(57) ABSTRACT

Aspects of the present disclosure involve overlapping flexible circuit boards. In general, a portable electronic device includes a rigid circuit board, a first flexible circuit board, and a second flexible circuit board. The first flexible circuit board is attached to a surface of the rigid circuit board using a first type of connection associated with a first temperature. The second flexible circuit board is attached to the same surface of the rigid circuit board as the first flexible circuit board using a second type of connection associated with a second temperature. The second flexible circuit board at least partially overlaps with the first flexible circuit board.

### PRIORITY

The disclosure claims the benefit under 35 U.S.C. § 119 (e) of U.S. Provisional Patent Application No. 63/656,946 entitled “Overlapping Flexible Circuit Boards”, filed on Jun. 6, 2024, which is incorporated herein by reference in its entirety.

### TECHNICAL FIELD

This disclosure relates generally to flexible circuit boards, and more specifically to overlapping flexible circuit boards.

### BACKGROUND

Many devices, such as portable electronic devices, include multiple flexible circuit boards. However, ensuring that multiple flexible circuit boards can fit within an allotted space in a device is a continual challenge. It is with these and other issues in mind that various aspects of the present disclosure were developed.

### SUMMARY

In one aspect, the disclosure is directed to a portable electronic device that includes overlapping flexible circuit boards. In general, the portable electronic device can include a rigid circuit board, a first flexible circuit board attached to a surface of the rigid circuit board using a first type of connection associated with a first temperature, and a second flexible circuit board attached to the same surface of the rigid circuit board as the first flexible circuit board using a second type of connection associated with a second temperature. The second flexible circuit board at least partially overlaps with the first flexible circuit board.

In a further aspect, the disclosure is directed to a method for attaching overlapping flexible circuit boards to a rigid circuit board. A first flexible circuit board can be attached to a surface of a rigid circuit board using a first type of connection associated with a first temperature. A second flexible circuit board can be attached to the same surface of the rigid circuit board as the first flexible circuit board using a second type of connection associated with a second temperature. The second flexible circuit board at least partially overlaps with the first flexible circuit board.

### BRIEF DESCRIPTION OF THE DRAWINGS

Although the following figures and description illustrate specific embodiments and examples, the skilled artisan will appreciate that various changes and modifications may be made without departing from the spirit and scope of the disclosure.

FIG. 1 is a side view of overlapping flexible circuit boards attached to a rigid circuit board; according to an illustrative embodiment;

FIG. 2 is a top view of overlapping flexible circuit boards attached to a rigid circuit board; according to an illustrative embodiment;

FIG. 3 illustrates an example method for attaching overlapping flexible circuit boards to a rigid circuit board; according to an illustrative embodiment; and

FIG. 4 is a portable electronic device, according to an illustrative embodiment.

### DETAILED DESCRIPTION

As noted above, aspects of the present disclosure involve a portable electronic device that includes overlapping flexible circuit boards. In general, the portable electronic device can include a rigid circuit board, a first flexible circuit board attached to a surface of the rigid circuit board using a first type of connection associated with a first temperature, and a second flexible circuit board attached to the same surface of the rigid circuit board as the first flexible circuit board using a second type of connection associated with a second temperature. The second flexible circuit board at least partially overlaps with the first flexible circuit board, such as in the z-direction.

Through this particular portable electronic device design, several advantages may be obtained over conventional portable electronic devices. For example, a conventional portable electronic device can include multiple flexible circuit boards attached to the same surface of the rigid board. A solder paste can be applied to the top surface and two flexible circuit boards can be attached to the same side of the board. However, if the channel where the two flexible circuit boards are route cannot increase in size, the width of the flexible circuit boards will be limited in the shared space. Thereby reducing the individual flex width exiting the solder attachment region. Locally reducing the flex width is not optimal for flex thermals or flex resistance.

Alternatively, flexible circuit boards can be attached to different surfaces of the same rigid circuit board. For example, a first flexible circuit board can first be attached to a top surface of a rigid circuit board, and a second flexible circuit board can subsequently be attached to a bottom surface of the rigid circuit board. However, attaching flexible circuit boards to different sides of the same rigid circuit board takes up valuable space within the portable electronic device. The flex attachment on the bottom side of the board causes the entire board, including the components on the top side, to shift up in Z. This Z shift can negatively impact the overall thickness of the system enclosure.

The improved portable electronic device described herein includes a first flexible circuit board and a second flexible circuit board attached to the same side of a rigid circuit board. The first flexible circuit board and the second flexible circuit board can at least partially overlap with each other, such as in the z-direction. Because the first flexible circuit board and the second flexible circuit board are attached to the same side of the rigid circuit board, valuable space is freed up within the portable electronic device, thereby eliminating the need to reduce the width of the first flexible circuit board and the second flexible circuit board and reduce the overall subassembly Z height.

In some embodiments, the first flexible circuit board can be attached to a surface of a rigid circuit board using a first type of connection. The first type of connection can be associated with a first temperature. The first flexible circuit board can be attached to the surface of the rigid circuit board using the first type of connection associated with the first temperature before the second flexible circuit board is attached to the same surface of the rigid circuit board using a second type of connection associated with a second temperature. The first temperature can be higher than the second temperature. While the second temperature is not high enough to damage the connection between the first flexible circuit board and the surface of the rigid circuit board, the second temperature is still high enough to attach the second flexible circuit board to the same surface of the rigid circuit board.

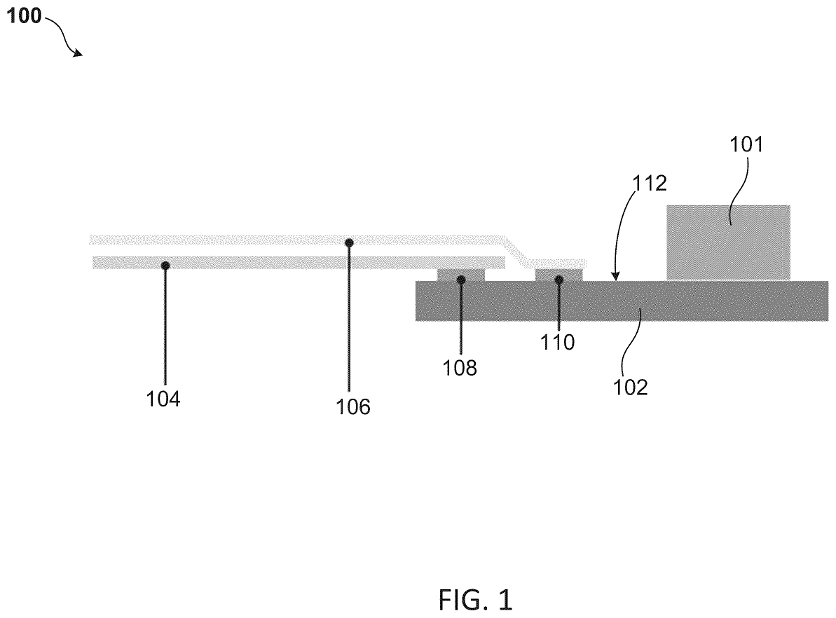

FIG. 1 is a side view 100 of overlapping flexible circuit boards attached to a rigid circuit board 102. In particular, a first flexible circuit board 104 is attached to a surface 112 of the rigid circuit board 102. The first flexible circuit board 104 can be configured to attach to a main logic board (MLB) of a device, such as a portable electronic device. The first flexible circuit board 104 can be a material comprising copper. The first flexible circuit board 104 can have a width. The first flexible circuit board 104 can be attached to the surface 112 of the rigid circuit board 102 using a connection 108. The connection 108 can be an electro-mechanical connection.

In embodiments, the connection 108 can be a first type of connection. The first type of connection can be associated with a first temperature. The first type of connection can be a high temperature surface mount technology (SMT) reflow connection. For example, the connection 108 can be a hot bar connection. The high temperature SMT reflow connection can be generated using a high temperature solder alloy. The high temperature solder alloy can include tin, silver, and copper.

In embodiments, the high temperature solder alloy can be disposed on or pasted on one or more locations on the surface 112 of the rigid circuit board 102. The high temperature solder alloy can be exposed to the first temperature. The first temperature is greater than or equal to a melting temperature of the high temperature solder alloy. The melting temperature of the high temperature solder alloy can be, for example, 200 degrees Celsius, 250 degrees Celsius, 300 degrees Celsius, or any other temperature. Exposing the high temperature solder alloy to the first temperature can cause the high temperature solder alloy to melt. The high temperature solder can be cooled down to bond the first flexible circuit board 104 to the surface 112 of the rigid circuit board 102. For example, the high temperature solder alloy that has cooled down can form the connection 108 between the first flexible circuit board 104 and the surface 112 of the rigid circuit board 102.

A second flexible circuit board 106 can be attached to the same surface 112 of the rigid circuit board 102. The second flexible circuit board 106 can be configured to attach to a battery pack or battery management unit (BMU) of a device, such as a portable electronic device. The second flexible circuit board 106 can be a material comprising copper. The second flexible circuit board 106 can have the same width as the first flexible circuit board 104. The second flexible circuit board 106 can be attached to the surface 112 of the rigid circuit board 102 using a connection 110. The connection 110 can be an electro-mechanical connection.

In embodiments, the connection 110 can be a second type of connection. The second type of connection can be associated with a second temperature. The first temperature can be higher than the second temperature. The second type of connection can be a low temperature SMT reflow connection. For example, the connection 110 can be a hot bar connection. The low temperature SMT reflow connection can be generated using a low temperature solder alloy. The low temperature solder alloy can include tin, silver, and bismuth.

In embodiments, the low temperature solder alloy can be dispensed on one or more different locations on the surface 112 of the rigid circuit board 102, such as on one or more locations that are different from the locations on which the high temperature solder alloy was disposed. The low temperature solder alloy can be exposed to the second temperature. The second temperature is greater than or equal to a melting temperature of the low temperature solder alloy. The second temperature can be less than the melting temperature of the high temperature solder alloy. The melting temperature of the low temperature solder alloy can be, for example, 100 degrees Celsius, 150 degrees Celsius, 175 degrees Celsius, or any other temperature. Exposing the low temperature solder alloy to the second temperature can cause the low temperature solder alloy to melt. The low temperature solder alloy can cool down to bond the second flexible circuit board 106 to the surface 112 of the rigid circuit board 102. For example, the low temperature solder alloy that has cooled down can form the connection 110 between the second flexible circuit board 106 and the surface 112 of the rigid circuit board 102. Because the second temperature is less than the melting point of the high temperature solder alloy, exposing the low temperature solder alloy to the second temperature does not cause the high temperature solder alloy to re-flow, thereby maintaining the integrity of the connection 108.

In embodiments, the first flexible circuit board 104 and the second flexible circuit board 106 at least partially overlap. The first flexible circuit board 104 and the second flexible circuit board 106 can at least partially overlap in the z-direction. If the first flexible circuit board 104 and the second flexible circuit board 106 at least partially overlap in the z-direction, this can save valuable z-height space within the device. Such a z-height space savings can allow for the development of thinner devices, such as devices that are 100 to 400 microns thinner than devices including flexible circuit boards that are attached to different sides of the same rigid circuit board.

The second flexible circuit board 106 can extend over the first flexible circuit board 104 so as to at least partially cover the first flexible circuit board 104 (or vice versa). The first flexible circuit board 104 and the second flexible circuit board 106 can completely overlap, such that the second flexible circuit board 106 extends over the first flexible circuit board 104 to cover the entirety of the first flexible circuit board 104 (or vice versa).

In embodiments, the first flexible circuit board 104 and the second flexible circuit board 106 can at least partially overlap such that neither the first flexible circuit board 104 nor the second flexible circuit board 106 extend above a device component 101 attached to the rigid circuit board 102. For example, a top surface of the second flexible circuit board 106 can be located at a distance D from the surface 112 along an axis that is perpendicular to the surface 112. The distance D can be less than or equal to a height H of the device component 101.

In embodiments, the first flexible circuit board 104 and the second flexible circuit board 106 can at least partially overlap such that there are no intervening device components positioned between the first flexible circuit board 104 and the second flexible circuit board 106. For example, the second flexible circuit board 106 can be located directly above the first flexible circuit board 104, with no other device components being positioned between the first flexible circuit board 104 and the second flexible circuit board 106.

As described above, the second flexible circuit board 106 can be configured to attach to a battery pack. The battery pack can include a battery stack and an enclosure enclosing the battery stack. The battery stack can include a plurality of layers comprising a cathode with an active coating, a separator, and an anode with an active coating. For example, the cathode can be an aluminum foil coated with a lithium compound (e.g., LiCoO₂, LiNCoMn, LiCoAl or LiMn₂O₄) and the anode can be a copper foil coated with carbon or graphite. The separator can include polyethylene (PE), polypropylene (PP), and/or a combination of PE and PP, such as PE/PP or PP/PE/PP.

The plurality of layers can be wound to form a jelly roll structure or can be stacked to form a stacked-cell structure. The plurality of layers may be enclosed within the enclosure and immersed in an electrolyte, which for example, can be a LiPF6-based electrolyte that can include Ethylene Carbonate (EC), Polypropylene Carbonate (PC), Ethyl Methyl Carbonate (EMC) or DiMethyl Carbonate (DMC). The electrolyte can also include additives such as Vinyl carbonate (VC) or Polyethylene Soltone (PS). The electrolyte can additionally be in the form of a solution or a gel.

The enclosure may comprise a plurality of faces (e.g., sides). For example, the enclosure may comprise a top face, a bottom face, and one or more side faces. However, it should be appreciated that the enclosure may be any size or shape and may include any number of faces and/or angles.

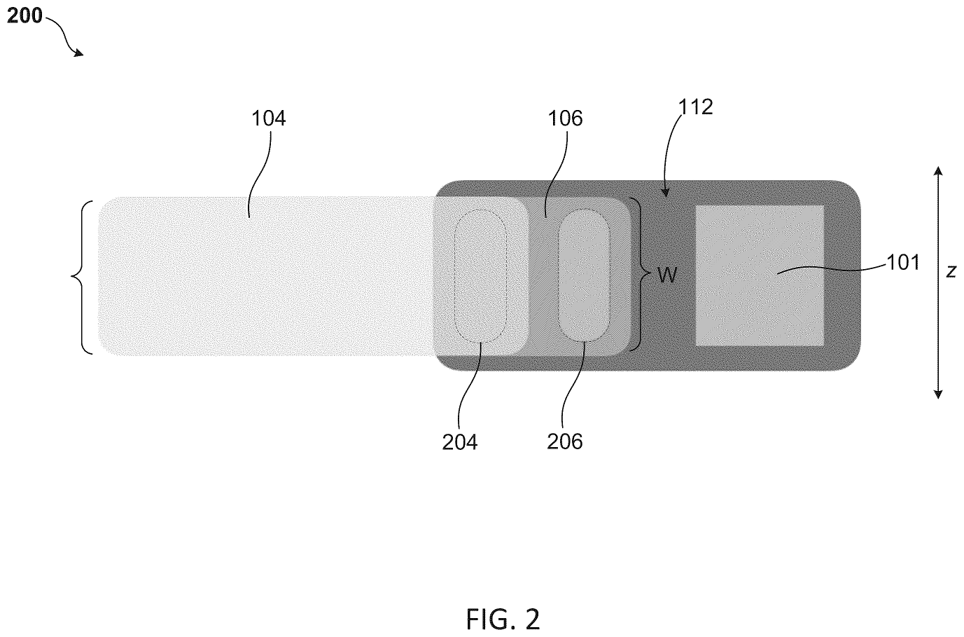

FIG. 2 is a top view of the first flexible circuit board 104 and the second flexible circuit board 106 attached to the rigid circuit board 102. The first flexible circuit board 104 and the second flexible circuit board 106 can at least partially overlap, such in the z-direction.

The first flexible circuit board 104 is attached to the surface 112 of the rigid circuit board 102. The first flexible circuit board 104 can have a width W. The first flexible circuit board 104 can be attached to the surface 112 of the rigid circuit board 102 using a first type of connection. The first type of connection can be associated with a first temperature. The first type of connection can be a high temperature SMT reflow connection. The high temperature SMT reflow connection can be generated using a high temperature solder alloy. The high temperature solder alloy can include tin, silver, and copper.

In embodiments, the high temperature solder alloy can be disposed on or pasted on one or more locations 204 on the surface 112 of the rigid circuit board 102. The high temperature solder alloy can be exposed to the first temperature. The first temperature is greater than or equal to a melting temperature of the high temperature solder alloy. The melting temperature of the high temperature solder alloy can be, for example, 200 degrees Celsius, 250 degrees Celsius, 300 degrees Celsius, or any other temperature. Exposing the high temperature solder alloy to the first temperature can cause the high temperature solder alloy disposed on the one or more locations 204 to melt. The high temperature solder alloy that has melted can be cooled down to form the first type of connection.

The second flexible circuit board 106 is attached to the surface 112 of the rigid circuit board 102. The second flexible circuit board 106 can have the width W. The second flexible circuit board 106 can be attached to the surface 112 of the rigid circuit board 102 using a second type of connection. The second type of connection can be associated with a second temperature. The second type of connection can be a low temperature SMT reflow connection. The low temperature SMT reflow connection can be generated using a low temperature solder alloy. The low temperature solder alloy can include tin, silver, and bismuth.

In embodiments, the low temperature solder alloy can be dispensed on one or more locations 206 on the surface 112 of the rigid circuit board 102. The low temperature solder alloy can be exposed to the second temperature. The second temperature is greater than or equal to a melting temperature of the low temperature solder alloy. The melting temperature of the low temperature solder alloy can be, for example, 100 degrees Celsius, 150 degrees Celsius, 175 degrees Celsius, or any other temperature. Exposing the low temperature solder alloy to the second temperature can cause the low temperature solder alloy disposed on the one or more locations 206 to melt. The low temperature solder alloy that has melted can be cooled down to form the second type of connection.

Because the second temperature is less than the melting point of the high temperature solder alloy, exposing the low temperature solder alloy to the second temperature does not cause the high temperature solder alloy to re-flow, thereby maintaining the integrity of the first type of connection.

As described above, the first flexible circuit board 104 and the second flexible circuit board 106 can be attached to the same surface 112 of the rigid circuit board 102 and can at least partially overlap in the z-direction. Additionally, or alternatively, the above-described techniques can be used to attach the first flexible circuit board 104 and the second flexible circuit board 106 to the same surface 112 of the rigid circuit board 102 such that the first flexible circuit board 104 and the second flexible circuit board 106 are adjacent to each other on the same surface 112 of the rigid circuit board 102.

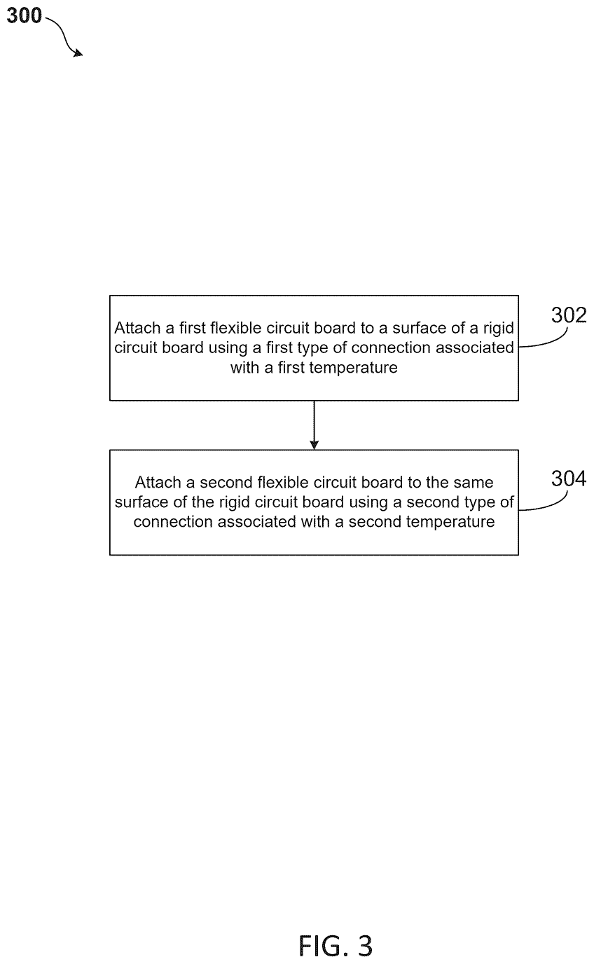

FIG. 3 illustrates an example method 300 for attaching overlapping flexible circuit boards, such as the first flexible circuit board 104 and the second flexible circuit board 106, to a rigid circuit board, such as the rigid circuit board 102, in accordance with various aspects of the subject technology. It should be understood that, for any process discussed herein, there can be additional, fewer, or alternative steps performed in similar or alternative orders, or in parallel, within the scope of the various embodiments unless otherwise stated.

At operation 302, the first flexible circuit board 104 is attached to the surface 112 of the rigid circuit board 102. The first flexible circuit board 104 can be attached to the surface 112 of the rigid circuit board 102 using a first type of connection. The first type of connection is associated with a first temperature.

In some embodiments, attaching the first flexible circuit board 104 to the surface 112 of the rigid circuit board 102 using the first type of connection associated with the first temperature can include attaching the first flexible circuit board 104 to the surface 112 of the rigid circuit board 102 using a high temperature SMT reflow connection. Attaching the first flexible circuit board 104 to the surface 112 of the rigid circuit board 102 using the high temperature SMT reflow connection can include pasting a high temperature solder alloy at one or more locations 204 on the surface 112 of the rigid circuit board 102. The high temperature solder alloy can include tin, silver and copper. Attaching the first flexible circuit board 104 to the surface 112 of the rigid circuit board 102 using the high temperature SMT reflow connection can include causing the high temperature solder alloy to melt by exposing the high temperature solder alloy to the first temperature. The first temperature can be greater than or equal to a melting temperature of the high temperature solder alloy. The high temperature solder alloy can have a melting temperature of 200 degrees Celsius, 250 degrees Celsius, 300 degrees Celsius, or any other temperature.

At operation 304, the second flexible circuit board 106 is attached to the same surface 112 of the rigid circuit board 102. The second flexible circuit board 106 can be attached to the surface 112 of the rigid circuit board 102 using a second type of connection. The second type of connection is associated with a second temperature. The first temperature can be higher than the second temperature. The second flexible circuit board can at least partially overlap with the first flexible circuit board. The first flexible circuit board and the second flexible circuit board can at least partially overlap in the z-direction.

In some embodiments, attaching the second flexible circuit board 106 to the surface 112 of the rigid circuit board 102 using the second type of connection associated with the second temperature can include attaching the second flexible circuit board 106 to the surface 112 of the rigid circuit board 102 using a low temperature SMT reflow connection. Attaching the second flexible circuit board 106 to the surface 112 of the rigid circuit board 102 using the low temperature SMT reflow connection can include pasting a low temperature solder alloy at one or more locations 206 on the surface 112 of the rigid circuit board 102. The low temperature solder alloy can include tin, silver and bismuth. Attaching the second flexible circuit board 106 to the surface 112 of the rigid circuit board 102 using the low temperature SMT reflow connection can include causing the low temperature solder alloy to melt by exposing the low temperature solder alloy to the second temperature. The second temperature can be greater than or equal to a melting temperature of the low-temperature solder alloy and less than the melting temperature of the high temperature solder alloy. The low-temperature solder alloy can have a melting temperature of 100 degrees Celsius, 150 degrees Celsius, 175 degrees Celsius, or any other temperature.

In embodiments, the first flexible circuit board 104 is attached to the surface 112 of the rigid circuit board 102 using the first type of connection associated with the first temperature before the second flexible circuit board 106 is attached to the same surface 112 of the rigid circuit board 102 using the second type of connection associated with the second temperature.

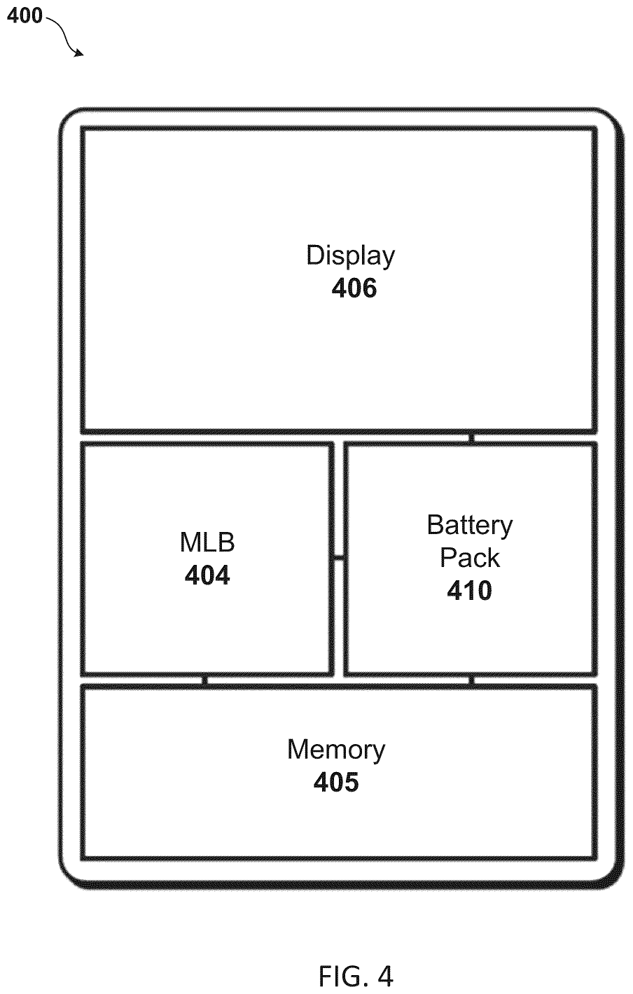

FIG. 4 illustrates a portable electronic device 400, in accordance with various aspects of the subject technology. The portable electronic device 400 includes a main logic board 404, a memory 405, and a display 406, which are all powered by a battery pack 410. Portable electronic device 400 may correspond to a laptop computer, tablet computer, mobile phone, personal digital assistant (PDA), digital music player, watch, and wearable device, and/or other type of battery-powered electronic device.

The main logic board 404 can be the main circuit board of the portable electronic device 400. The main logic board 404 can include one or more of a central processing unit, a main system memory, and circuitry that controls the components of the portable electronic device 400 and/or other peripheral devices.

The battery pack 410 can include a battery stack and an enclosure enclosing the battery stack. The battery stack can include a plurality of layers comprising a cathode with an active coating, a separator, and an anode with an active coating. For example, the cathode can be an aluminum foil coated with a lithium compound (e.g., LiCoO₂, LiNCoMn, LiCoAl or LiMn₂O₄) and the anode can be a copper foil coated with carbon or graphite. The separator can include polyethylene (PE), polypropylene (PP), and/or a combination of PE and PP, such as PE/PP or PP/PE/PP.

The plurality of layers can be wound to form a jelly roll structure or can be stacked to form a stacked-cell structure. The plurality of layers may be enclosed within the enclosure and immersed in an electrolyte, which for example, can be a LiPF6-based electrolyte that can include Ethylene Carbonate (EC), Polypropylene Carbonate (PC), Ethyl Methyl Carbonate (EMC) or DiMethyl Carbonate (DMC). The electrolyte can also include additives such as Vinyl carbonate (VC) or Polyethylene Soltone (PS). The electrolyte can additionally be in the form of a solution or a gel.

The enclosure may comprise a plurality of faces (e.g., sides). For example, the enclosure may comprise a top face, a bottom face, and one or more side faces. However, it should be appreciated that the enclosure may be any size or shape and may include any number of faces and/or angles.

The first flexible circuit board 104 can be configured to attach to the main logic board 404. The second flexible circuit board 106 can be configured to attach to the battery pack 410. The first flexible circuit board 104 can be attached to a surface of a rigid circuit board using a first type of connection associated with a first temperature. The second flexible circuit board 106 can be attached to the same surface of the rigid circuit board as the first flexible circuit board 104 using a second type of connection associated with a second temperature.

The first flexible circuit board 104 and the second flexible circuit board 106 can at least partially overlap. The first flexible circuit board 104 and the second flexible circuit board 106 can at least partially overlap in the z-direction. The second flexible circuit board 106 can extend over the first flexible circuit board 104 so as to at least partially cover the first flexible circuit board 104 (or vice versa). The first flexible circuit board 104 and the second flexible circuit board 106 can at least partially overlap such that there are no intervening components of the portable electronic device 400 positioned between the first flexible circuit board 104 and the second flexible circuit board 106. For example, the second flexible circuit board 106 can be located directly above the first flexible circuit board 104, with no other device components being positioned between the first flexible circuit board 104 and the second flexible circuit board 106. The first flexible circuit board 104 and the second flexible circuit board 106 can completely overlap, such that the second flexible circuit board 106 extends over the first flexible circuit board 104 to cover the entirety of the first flexible circuit board 104 (or vice versa).

The battery cans, battery assemblies, and various non-limiting components and embodiments as described herein can be used with various electronic devices. Such electronic devices can be any electronic devices known in the art. For example, the device can be a telephone, such as a mobile phone, and a land-line phone, or any communication device, such as a smart phone, including, for example an iPhone®, and an electronic email sending/receiving device. The battery cans, battery assemblies, and various non-limiting components and embodiments as described herein can be used in conjunction with a display, such as a digital display, a TV monitor, an electronic-book reader, a portable web-browser (e.g., iPad®), watch and a computer monitor. The device can also be an entertainment device, including a portable DVD player, conventional DVD player, Blue-Ray disk player, video game console, music player, such as a portable music player (e.g., iPod®), etc. Devices include control devices, such as those that control the streaming of images, videos, sounds (e.g., Apple TV®), or a remote control for a separate electronic device. The device can be a part of a computer or its accessories, laptop keyboard, laptop track pad, desktop keyboard, mouse, and speaker.

While the present disclosure has been described with reference to various implementations, it will be understood that these implementations are illustrative and that the scope of the disclosure is not limited to them. Many variations, modifications, additions, and improvements are possible. More generally, implementations in accordance with the present disclosure have been described in the context of particular implementations. Functionality may be separated or combined in blocks differently in various embodiments of the disclosure or described with different terminology. These and other variations, modifications, additions, and improvements may fall within the scope of the disclosure as defined in the claims that follow.

What is claimed is:

1. A portable electronic device comprising:
a rigid circuit board;
a first flexible circuit board attached to a surface of the rigid circuit board using a first type of connection associated with a first temperature; and
a second flexible circuit board attached to the same surface of the rigid circuit board as the first flexible circuit board using a second type of connection associated with a second temperature,
wherein the second flexible circuit board at least partially overlaps with the first flexible circuit board.

2. The portable electronic device of claim 1, wherein the first type of connection associated with the first temperature is a high temperature surface mount technology (SMT) reflow connection.

3. The portable electronic device of claim 2, wherein the high temperature SMT reflow connection is generated using a solder alloy comprising tin, silver and copper.

4. The portable electronic device of claim 2, wherein the high temperature SMT reflow connection is generated using a solder alloy having a melting temperature greater than 200 degrees Celsius.

5. The portable electronic device of claim 1, wherein the second type of connection associated with the second temperature is a low temperature surface mount technology (SMT) reflow connection.

6. The portable electronic device of claim 5, wherein the low temperature SMT reflow connection is generated using a solder alloy comprising tin, silver, and bismuth.

7. The portable electronic device of claim 5, wherein the low temperature SMT reflow connection is generated using a solder alloy that melts at temperatures greater than 100 degrees Celsius.

8. The portable electronic device of claim 1, wherein the first flexible circuit board and the second flexible circuit board have substantially a same width.

9. The portable electronic device of claim 1, wherein the second flexible circuit board at least partially overlaps with the first flexible circuit board in the z-direction.

10. The portable electronic device of claim 1, wherein the first flexible circuit board and the second flexible circuit board are a material comprising copper.

11. A method comprising:
attaching a first flexible circuit board to a surface of a rigid circuit board using a first type of connection associated with a first temperature; and
attaching a second flexible circuit board to the same surface of the rigid circuit board as the first flexible circuit board using a second type of connection associated with a second temperature; and
wherein the second flexible circuit board at least partially overlaps with the first flexible circuit board.

12. The method of claim 11, wherein the first temperature is higher than the second temperature.

13. The method of claim 11, wherein attaching the first flexible circuit board to the surface of the rigid circuit board using the first type of connection associated with the first temperature comprises attaching the first flexible circuit board to the surface of the rigid circuit board using a high temperature surface mount technology (SMT) reflow connection, and
wherein attaching the second flexible circuit board to the same surface of the rigid circuit board using the second type of connection associated with the second temperature comprises attaching the second flexible circuit board to the same surface of the rigid circuit board using a low temperature SMT reflow connection.

14. The method of claim 13, wherein attaching the first flexible circuit board to the surface of the rigid circuit board using the high temperature SMT reflow connection comprises:
pasting a high temperature solder alloy at one or more locations on the surface of the rigid circuit board;
causing the high temperature solder alloy to melt by exposing the high temperature solder alloy to a temperature that is greater than or equal to a melting temperature of the high temperature solder alloy; and
cooling the melted high temperature solder alloy down to form a bond between the first flexible circuit board and the surface of the rigid circuit board.

15. The method of claim 14, wherein the high temperature solder alloy comprises tin, silver and copper.

16. The method of claim 14, wherein the high temperature solder alloy has a melting temperature of 200 degrees Celsius.

17. The method of claim 14, wherein attaching the second flexible circuit board to the surface of the rigid circuit board using the low temperature SMT reflow connection comprises:
dispensing a low-temperature solder alloy at one or more different locations on the surface of the rigid circuit board;
causing the low-temperature solder alloy to melt by exposing the low-temperature solder alloy to a temperature that is greater than or equal to a melting temperature of the low-temperature solder alloy and less than the melting temperature of the high temperature solder alloy; and
cooling the melted low temperature solder alloy down to form a bond between the second flexible circuit board and the surface of the rigid circuit board.

18. The method of claim 17, wherein the low-temperature solder alloy comprises tin, silver, and bismuth.

19. The method of claim 17, wherein the low-temperature solder alloy has a melting temperature of 100 degrees Celsius.

20. The method of claim 11, wherein the first flexible circuit board is attached to the surface of the rigid circuit board using the first type of connection associated with the first temperature before the second flexible circuit board is attached to the same surface of the rigid circuit board using the second type of connection associated with the second temperature.
